(19) United States
(12) Patent Application Publication
(10) Pub. No.: US 2025/0062286 A1
(43) Pub. Date: Feb. 20, 2025

(54) SEMICONDUCTOR PACKAGE AND MANUFACTURING METHOD THEREOF

(71) Applicant: SAMSUNG ELECTRONICS CO., LTD., Suwon-si (KR)

(72) Inventors: Hyunsoo Chung, Suwon-si (KR); Kwang-Soo Kim, Suwon-si (KR); Jun Gul Hwang, Suwon-si (KR)

(21) Appl. No.: 18/588,462

(22) Filed: Feb. 27, 2024

(30) Foreign Application Priority Data
Aug. 17, 2023 (KR) 10-2023-0107502

(51) Int. Cl. H01L 25/065; H01L 21/56; H01L 23/00; H01L 23/31; H01L 23/48; H10B 80/00

(52) U.S. Cl. CPC H01L 25/0657; H01L 21/565; H01L 23/3128; H01L 23/481; H01L 24/08; H01L 24/94; H01L 24/96; H01L 24/97; H10B 80/00; H01L 2224/08145; H01L 2224/08235; H01L 2224/94; H01L 2224/96; H01L 2224/97; H01L 2225/06544; H01L 2225/06548; H01L 2225/06555; H01L 2924/1431

(57) ABSTRACT

A semiconductor package includes a first semiconductor chip having a front side and a back side that is opposite to the front side, the first semiconductor chip includes a front side wiring structure disposed on the front side, a back side wiring structure disposed on the back side, and a first through via electrically connected to the front side wiring structure and the back side wiring structure, a second semiconductor chip disposed on the back side of the first semiconductor chip and including a second through via, and a third semiconductor chip disposed on the front side of the first semiconductor chip, wherein the first semiconductor chip receives power through the second through via, and wherein a thickness of the second semiconductor chip is greater than a thickness of the first semiconductor chip.

### CROSS-REFERENCE TO RELATED APPLICATION

This application claims priority to and the benefit from Korean Patent Application No. 10-2023-0107502, filed in the Korean Intellectual Property Office on Aug. 17, 2023, the disclosure of which is incorporated herein by reference in its entirety.

### BACKGROUND

In the semiconductor industry, chiplet technology is designed to overcome problems, such as production cost, production difficulty, and yield deterioration of monolithic technology that integrates various functions into one chip, is attracting attention. The chiplet technology produces a single package by connecting several semiconductor chips with different functions to each other through a high-speed interconnect.

In general, a 3-dimensional integrated circuit (3D-IC) structure may be applied to the semiconductor package by disposing and packaging an upper semiconductor chip on a lower semiconductor chip in the vertical direction. For example, a semiconductor chip for covering logic functions with a relatively large area may be disposed at a bottom, and a semiconductor chip for covering a memory with a relatively narrow area and analog input/output functions, etc. may be disposed at a top, thereby manufacturing a 3D integrated circuit.

In the 3D integrated circuit structure, heat generated from the semiconductor chip disposed at the bottom is difficult to be efficiently dissipated to the outside of the semiconductor package due to the semiconductor chip disposed at the top, and the heat dissipation characteristic of the semiconductor package is deteriorated. In addition, when disposing the logic chip on the top to improve the heat dissipation characteristic, it is important to improve the power characteristic of the logic chip.

### SUMMARY

In general, in some aspects, the present disclosure is directed toward a semiconductor package having improved heat dissipation characteristics and a manufacturing method thereof. Additionally, the present disclosure is directed toward a semiconductor package for improving power characteristic and for reducing manufacturing cost and a manufacturing method thereof.

According to some aspects of the present disclosure, a semiconductor package includes: a first semiconductor chip having a front side and a back side that is opposite to the front side, and including a front side wiring structure disposed on the front side, a back side wiring structure disposed on the back side, and a first through via electrically connected to the front side wiring structure and the back side wiring structure; a second semiconductor chip disposed on the back side of the first semiconductor chip and including a second through via; and a third semiconductor chip disposed on the front side of the first semiconductor chip, wherein the first semiconductor chip receives power through the second through via, and a thickness of the second semiconductor chip is greater than a thickness of the first semiconductor chip.

According to some aspects of the present disclosure, a semiconductor package includes: a first semiconductor chip having a front side and a back side that is opposite to the front side, and including a front side wiring structure disposed on the front side, a back side wiring structure disposed on the back side, and a first through via electrically connected to the front side wiring structure and the back side wiring structure; a second semiconductor chip disposed on the back side of the first semiconductor chip and including a second through via electrically connected to the first semiconductor chip; a third semiconductor chip disposed on the front side of the first semiconductor chip; an encapsulant for encapsulating at least a portion of the second semiconductor chip; and a rewiring structure disposed on the second semiconductor chip, wherein a diameter of the first through via is less than a diameter of the second through via.

According to some aspects of the present disclosure a method for manufacturing a semiconductor package includes: providing a first wafer structure in which a first front side wiring structure is formed; providing a second wafer structure in which a second front side wiring structure is formed; bonding the first wafer structure and the second wafer structure; forming a first through via in the second wafer structure to be connected to the second front side wiring structure; forming a back side wiring structure in the second wafer structure to be connected to the first through via; disposing a semiconductor chip including a second through via on the second wafer structure; and dicing the bonded first wafer structure and the second wafer structure.

### BRIEF DESCRIPTION OF THE DRAWINGS

FIG. 1 shows a cross-sectional view of an example of a semiconductor package according to some implementations.

FIG. 2 shows a cross-sectional view of an example of a semiconductor package according to some implementations.

FIG. 3 shows a cross-sectional view of an example of a semiconductor package according to some implementations.

FIG. 4 shows a cross-sectional view of an example of a 2.5D package including a semiconductor package according to some implementations.

FIG. 5 shows a cross-sectional view of an example of a package on package (POP) including a semiconductor package according to some implementations.

FIG. 6A to FIG. 6H show examples of processing diagrams for manufacturing a semiconductor package according to some implementations.

### DETAILED DESCRIPTION

Hereinafter, example implementations will be described in detail with reference to the accompanying drawings.

In some implementations, the size and thickness of each configuration shown in the drawings are arbitrarily shown for better understanding and ease of description, but the present disclosure is not limited thereto. In the drawings, the thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

Throughout the present disclosure and claims that follow, when it is described that an element is “coupled” to another element, the element may be “directly coupled” to the other element or “indirectly coupled” to the other element through a third element. In a similar sense, this includes being “physically connected” as well as being “electrically connected”. In addition, unless explicitly described to the contrary, the word “comprise”, and variations such as “comprises” or “comprising”, will be understood to imply the inclusion of stated elements but not the exclusion of any other elements.

In some implementations, sequential numbers, such as first and second, are used to distinguish a constituent element from other constituent elements that are the same or similar to it, and are not necessarily intended to refer to a specific constituent element. Accordingly, a component referred to as the first constituent element in one part of the present disclosure may be referred to as a second constituent element in another part of the present disclosure.

In some implementations, references to any constituent element in the singular form include references to plurality of those constituent elements, unless specifically stated to the contrary. For example, an “insulation layer” may be used to mean not only one insulation layer, but also a plurality of insulation layers, such as two, three or more.

In some implementations, references to one side and the other side are intended to distinguish between different sides, and are not necessarily intended to limit it to a specific side. Accordingly, a side referred to as one side in a particular part of the present disclosure may be referred to as the other side in other parts of the present disclosure.

In some implementations, an upper side is described as a direction from a first semiconductor chip 100 to a third semiconductor chip 300, and a lower side is described as a direction from the first semiconductor chip 100 to a second semiconductor chip 200.

In some implementations, a numerical range may include both arbitrary values and arbitrary ranges within a limited numerical range. For example, 1 to 10 includes 1 and 10, any value between 1 to 10 (e.g., 2, 5 or 7), and any range between 1 to 10 (e.g., 3 to 5, 3.5 to 6, or 9.0 to 9.9) are included.

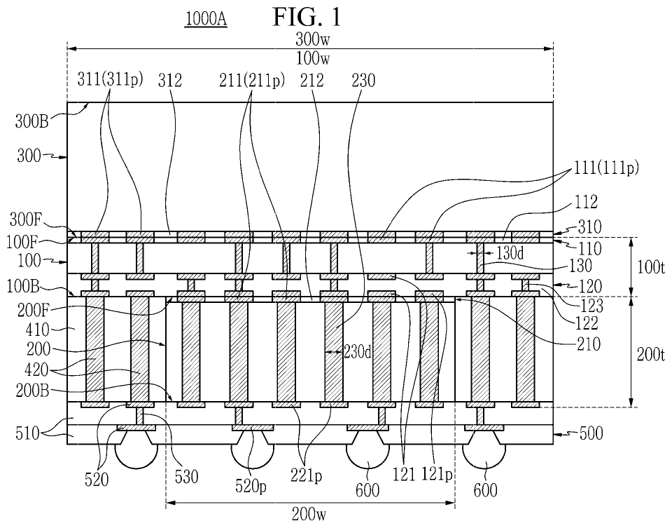

FIG. 1 shows a cross-sectional view of an example of a semiconductor package according to some implementations. In FIG. 1, a semiconductor package 1000A includes a first semiconductor chip 100, a second semiconductor chip 200, and a third semiconductor chip 300. The semiconductor package 1000A may further include at least one of an encapsulant 410, a through via 420, a rewiring structure 500, and a connection structure 600. The first semiconductor chip 100 may have a front side 100F and a back side 100B that is an opposite side to the front side 100F, and may include a front side wiring structure 110 disposed on the front side 100F, a back side wiring structure 120 disposed on the back side 100B, and a first through via 130 electrically connected to the front side wiring structure 110 and the back side wiring structure 120.

The front side wiring structure 110 may include a wiring layer 111 and an insulation layer 112. In some implementations, the front side wiring structure 110 is shown to include a wiring layer 111 and an insulation layer 112, nut may include wiring layers 111 and insulation layers 112. The front side wiring structure 110 may further include a via for connecting the wiring layers 111 to each other in a like way of the back side wiring structure 120.

The back side wiring structure 120 may include a wiring layer 121, an insulation layer 122, and a via 123. In some implementations, the back side wiring structure 120 is shown to include wiring layers 121 and insulation layers 122, but it may include a wiring layer 121 and an insulation layer 122. In some implementations, the back side wiring structure 120 may include a greater number of the wiring layers 121, the insulation layers 122, and/or the vias 123 than what is shown in FIG. 1. Conductive materials may be used for the wiring layers 111 and 121 and the via 123, for example, aluminum (Al), copper (Cu), gold (Au), silver (Ag), platinum (Pt), tin (Sn), chromium (Cr), palladium (Pd), lead (Pb), titanium (Ti), or alloys thereof may be used.

Insulating materials may be used for the insulation layers 112 and 122, for example, silicon oxide, silicon nitride, or a polymer such as a polyimide or benzocyclobutene (BCB) may be used. When the insulation layers 112 and 122 are plurality of insulation layers 112 and 122, respective materials of the plurality of insulation layers 112 and 122 may be the same or different.

In some implementations, the first semiconductor chip 100 may include connection pads 111p and 121p, and may be electrically connected to other elements through the connection pads 111p and 121p. For example, the front side wiring structure 110 of the first semiconductor chip 100 may include a first connection pad 111p, the back side wiring structure 120 may include a second connection pad 121p, and by this, the first semiconductor chip 100 may be electrically connected to the third semiconductor chip 300 and the second semiconductor chip 200.

The first connection pad 111p may be included in a headmost side wiring layer 111 from among the wiring layer 111 of the front side wiring structure 110. The first connection pad 111p may be hybrid-bonded to a fourth connection pad 311p of the third semiconductor chip 300. In some implementations, the first connection pad 111p may directly contact the fourth connection pad 311p and may be bonded thereto. In some implementations, the first connection pad 111p may be indirectly bonded to the fourth connection pad 311p through a bump, depending on designs. When the hybrid-bonding is applied, fine pitches may be realized, the semiconductor package may be made slim, and reliability may be improved.

The insulation layer 112 may be disposed on a side of the first connection pad 111p. When the first semiconductor chip 100 and the third semiconductor chip 300 are connected by the hybrid-bonding, the insulation layer 112 disposed on the side of the first connection pad 111p may directly contact an insulation layer 312 disposed on a side of the fourth connection pad 311p and may be bonded to the same. However, there may be a gap between the insulation layers 112 and 312 depending on materials of the insulation layer 112 disposed on the side of the first connection pad 111p and the insulation layer 312 disposed on the side of the fourth connection pad 311p, and formation methods thereof.

The second connection pad 121p may be included in a backmost side wiring layer 121 from among the wiring layer 121 of the back side wiring structure 120. The second connection pad 121p may be hybrid-bonded to a third connection pad 211p of the second semiconductor chip 200. In some implementations, the second connection pad 121p may directly contact the third connection pad 211p and may be bonded to the same. However, in some implementations, the second connection pad 121p may be indirectly bonded to the third connection pad 211p through the bump.

The insulation layer 122 may be disposed on a side of the second connection pad 121p. When the first semiconductor chip 100 and the second semiconductor chip 200 are connected by the hybrid-bonding, the insulation layer 122 disposed on a side of the second connection pad 121p may directly contact the insulation layer 212 disposed on a side of the third connection pad 211p and may be bonded to the same. However, there may be a gap between the insulation layers 122 and 212 depending on forming materials of the insulation layer 122 disposed on a side of the second connection pad 121p and the insulation layer 212 disposed on a side of the third connection pad 211p, and processes thereof.

The first through via 130 may be electrically connected to the front side wiring structure 110 and the back side wiring structure 120 to electrically connect them. The second semiconductor chip 200 may pass through the first semiconductor chip 100 through the first through via 130, and may be connected to the third semiconductor chip 300. The third semiconductor chip 300 may pass through the first semiconductor chip 100 through the first through via 130, and may be connected to the second semiconductor chip 200 and/or the rewiring structure 500.

In some implementations, a via-last method may be used for forming the first through via 130. In some implementations, a via-first method or a via-middle method may also be used. In some implementations, the method for forming the first through via 130 may use a PVD process, a CVD process, or a plating process. A region of the first semiconductor chip 100 penetrated by the first through via 130 may be changed, and is not limited to the region shown in FIG. 1. For example, in some implementations, the first through via 130 may further penetrate at least a portion of the back side wiring structure 120. The conductive material may be used as a material of the first through via 130, for example, tungsten (W), copper (Cu), aluminum (Al), and doped polysilicon may be used.

In some implementations, a diameter 130d of the first through via 130 may be less than a diameter 230d of the second through via 230. For example, the diameter 130d of the first through via 130 may be 0.1 to 1 μm.

A width 100w of the first semiconductor chip 100 may be greater than a width 200w of the second semiconductor chip 200. As described below, the first semiconductor chip 100 may be a chip with a relatively big area, for example, a chip including a logic circuit, that generates/may generate much heat or may have a front-end node, and hence, the width 100w of the first semiconductor chip 100 may be greater than the width 200w of the second semiconductor chip 200.

The width 100w of the first semiconductor chip 100 may be substantially equivalent to the width 300w of the third semiconductor chip 300. As described below, the first semiconductor chip 100 and the third semiconductor chip 300 may be formed by combining a second wafer structure 100′ and a first wafer structure 300′ in a wafer state by a wafer to wafer bonding method and dicing the same, and hence, the width 100w of the first semiconductor chip 100 may be substantially equivalent to the width 300w of the third semiconductor chip 300. In some implementations, the substantial equivalence includes a range of equivalence that may be accepted within an error range, such as processes or measurement, as well as physically complete equivalence. For example, the substantial equivalence may include the error range of 99.9%, 99.8%, 99.7%, 99.5%, 99%, 98.5%, 98%, or 97%.

A length of the first semiconductor chip 100 may be greater than a length of the second semiconductor chip 200. In some implementations, the length of the first semiconductor chip 100 may be less than/substantially equivalent to the length of the second semiconductor chip 200. Here, the length represents a length in a direction that is vertical to the width in a plan view.

Further, the length of the first semiconductor chip 100 may be substantially equivalent to the length of the third semiconductor chip 300. As described above, the first semiconductor chip 100 and the third semiconductor chip 300 may be formed by combining the second wafer structure 100′ and the first wafer structure 300′ in a wafer state by the wafer to wafer bonding method and dicing the same, and hence, the length of the first semiconductor chip 100 substantially equivalent to the length of the third semiconductor chip 300. In some implementations, the length of the first semiconductor chip 100 may be greater/less than the length of the third semiconductor chip 300.

In some implementations, a thickness 100t of the first semiconductor chip 100 may be less than a thickness 200t of the second semiconductor chip 200. For example, the thickness 100t of the first semiconductor chip 100 may be less than the thickness 200t of the second semiconductor chip 200 by at least 2, 3, 4, 5, 7, 9 or 10 times.

The thickness 100t of the first semiconductor chip 100 may be 2 to 10 μm. As described below, the thickness of the second wafer structure 100′ may be reduced by processing (e.g., grinding) a wafer of the second wafer structure 100′ in a wafer state before being diced with the first semiconductor chip 100, and by this, the first semiconductor chip 100 may be thin.

In some implementations, the first semiconductor chip 100 may include a logic circuit. However, in some implementations, the first semiconductor chip 100 may include a memory circuit, an input/output circuit or an analog circuit.

The first semiconductor chip 100 may receive power through the second through via 230. For example, the first semiconductor chip 100 may receive power through the second through via 230 and the back side wiring structure 120 of the first semiconductor chip 100. Accordingly, as the back side wiring structure 120 for supplying power is formed by using the front side 100F and the back side 100B of the first semiconductor chip 100, the semiconductor package 1000A may fluently supply power to the first semiconductor chip 100 disposed on an upper side, may reduce a wiring density of the front side wiring structure 110, and may increase a wiring freedom.

The second semiconductor chip 200 may be disposed on the back side 100B of the first semiconductor chip 100 and may include a second through via 230. The second semiconductor chip 200 may have a front side 200F and a back side 200B. In some implementations, the second semiconductor chip 200 may be disposed so that the front side 200F may face the back side 100B of the first semiconductor chip 100. For example, the second semiconductor chip 200 may be disposed in a face-up form so that the third connection pad 211p may face an upper side of a semiconductor package 1000B. Accordingly, the back side 200B of the second semiconductor chip 200 may face the rewiring structure 500.

The second semiconductor chip 200 may include a front side wiring structure 210 disposed on the front side 200F, and the front side wiring structure 210 may include a wiring layer 211 and an insulation layer 212. Further, the front side wiring structure 210 may further include a via for connecting the wiring layers 211 in a like way of the back side wiring structure 120 of the first semiconductor chip 100.

In some implementations, a via pad 221p for an electrical connection between the second through via 230 and the rewiring structure 500 may be disposed on the back side 200B of the second semiconductor chip 200. In some implementations, differing from the back side 100B of the first semiconductor chip 100, no additional back side wiring structure except the second through via 230 and the via pad 221p may be formed on the back side 200B of the second semiconductor chip 200. By this, a signal transmission path of the first semiconductor chip 100 and resistance may be reduced, a power characteristic such as power integrity (PI) of the first semiconductor chip 100 may be improved, and a manufacturing cost may be minimized. However, when the second through via 230 is directly electrically connected to the rewiring structure 500, the via pad 221p may not be disposed on the back side 200B of the second semiconductor chip 200.

The conductive materials may be used for the wiring layer 211 and the via pad 221p, for example, aluminum (Al), copper (Cu), gold (Au), silver (Ag), platinum (Pt), tin (Sn), chromium (Cr), palladium (Pd), lead (Pb), titanium (Ti), or alloys thereof may be used.

An insulating material may be used as a material for the insulation layer 212, for example, a silicon oxide, a silicon nitride, or a polymer such as polyimide or benzocyclobutene (BCB) may be used. When the insulation layer 212 includes plurality of insulation layers 212, the respective materials of the insulation layers 212 may be the same or different.

In some implementations, the second semiconductor chip 200 may include the third connection pad 211p. For example, the front side wiring structure 210 of the second semiconductor chip 200 may include the third connection pad 211p, and by this, the second semiconductor chip 200 may be electrically connected to the first semiconductor chip 100.

When the wiring layer 211 includes a plurality of wiring layers 211, the third connection pad 211p may be included in the headmost side wiring layer 211 from among the wiring layers 211 of the front side wiring structure 210. As described above, the third connection pad 211p may be hybrid-bonded to the second connection pad 121p of the first semiconductor chip 100.

The insulation layer 212 may be disposed on a side of the third connection pad 211p. When the first semiconductor chip 100 and the second semiconductor chip 200 are connected by the hybrid-bonding, the insulation layer 212 disposed on a side of the third connection pad 211p may directly contact the insulation layer 122 disposed on a side of the second connection pad 121p and may be bonded to the same. However, there may be a gap between the two insulation layers depending on forming materials of the insulation layer 212 disposed on a side of the third connection pad 211p and the second connection pad 121p, and processes thereof.

In some implementations, the second through via 230 may be electrically connected to the first semiconductor chip 100, and the first semiconductor chip 100 may receive power through the second through via 230. For example, as the second through via 230 is electrically connected to the third connection pad 211p of the second semiconductor chip 200, it may also be electrically connected to the first semiconductor chip 100, such that the second through via 230 may be electrically connected to the rewiring structure 500. Accordingly, the second through via 230 may receive power from the rewiring structure 500 and may supply power to the first semiconductor chip 100.

The via-middle method may be used to form the second through via 230, and without being limited thereto, the via-first method or the via-last method may also be used. Further, the method for forming the second through via 230 may use the PVD process, the CVD process, or the plating process. The second through via 230 is shown to penetrate (extend into) the second semiconductor chip 200 in the thickness direction in FIG. 1, and it may penetrate a portion of the second semiconductor chip 200 in the thickness direction. In some implementations, the second through via 230 may be indirectly connected to the third connection pad 211p. The conductive material may be used as the material of the second through via 230, for example, tungsten (W), copper (Cu), aluminum (Al), and doped polysilicon may be used.

As described above, in some implementations, the diameter 230d of the second through via 230 may be greater than the diameter 130d of the first through via 130. For example, the diameter 230d of the second through via 230 may be 2 to 50 μm.

As described above, the width 200w of the second semiconductor chip 200 may be less than the width 100w of the first semiconductor chip 100.

In some implementations, the thickness 200t of the second semiconductor chip 200 may be greater than the thickness 100t of the first semiconductor chip 100. For example, the thickness 200t of the second semiconductor chip 200 may be 20 to 100 μm.

The second semiconductor chip 200 may include an input/output circuit and/or an analog circuit. However, in some implementations, the second semiconductor chip 200 may include a memory circuit. However, in some implementations, it may be desirable for the second semiconductor chip 200 to not include the logic circuit with much heat in the viewpoint of heat dissipation.

The third semiconductor chip 300 may be disposed on the front side 100F of the first semiconductor chip 100. The third semiconductor chip 300 may also have the front side 300F and the back side 300B. In some implementations, the third semiconductor chip 300 may be disposed so that the front side 300F faces the front side 100F of the first semiconductor chip 100.

The third semiconductor chip 300 may include a front side wiring structure 310 disposed on the front side 300F. The front side wiring structure 310 may include the wiring layer 311 and the insulation layer 312. Additionally, the front side wiring structure 310 may further include a via for connecting the wiring layers 311 in a like way of the back side wiring structure 120 of the first semiconductor chip 100.

Differing from the back side 100B of the first semiconductor chip 100, no additional back side wiring structure may be formed on the back side 300B of the third semiconductor chip 300, thereby minimizing the manufacturing cost. In some implementations, the back side 300B of the third semiconductor chip 300 may be exposed outside the semiconductor package 1000A. Accordingly, the heat dissipation characteristic of the semiconductor package 1000A may be further improved.

Conductive materials may be used for the wiring layer 311, for example, aluminum (Al), copper (Cu), gold (Au), silver (Ag), platinum (Pt), tin (Sn), chromium (Cr), palladium (Pd), lead (Pb), titanium (Ti), or alloys thereof may be used.

The insulating material may be used as the material of the insulation layer 312, for example, a silicon oxide, a silicon nitride, or a polymer such as polyimide or benzocyclobutene (BCB) may be used. When the insulation layer 312 includes plurality of insulation layers 312, the respective materials of the insulation layers 312 may be the same or different.

In some implementations, the third semiconductor chip 300 may include a fourth connection pad 311p. For example, the front side wiring structure 310 of the third semiconductor chip 300 may include a fourth connection pad 311p, and by this, the third semiconductor chip 300 may be electrically connected to the first semiconductor chip 100.

When the wiring layer 311 includes plurality of wiring layers 311, the fourth connection pad 311p may be included in the headmost side wiring layer 311 from among the wiring layer 311 of the front side wiring structure 310. As described above, the fourth connection pad 311p may be hybrid-bonded to the first connection pad 111p of the first semiconductor chip 100.

The insulation layer 312 may be disposed on a side of the fourth connection pad 311p. When the first semiconductor chip 100 and the third semiconductor chip 300 are connected by hybrid-bonding, the insulation layer 312 disposed on a side of the fourth connection pad 311p may directly contact the insulation layer 112 disposed on a side of the first connection pad 111p and may be bonded to the same. However, there may be a gap between the two insulation layers depending on materials of the insulation layer 312 disposed on a side of the fourth connection pad 311p and the insulation layer 112 disposed on a side of the first connection pad 111p, and forming methods thereof.

In some implementations, the third semiconductor chip 300 may receive power through the first semiconductor chip 100. Accordingly, power may be efficiently supplied to the first semiconductor chip 100 and the third semiconductor chip 300 through the back side wiring structure 120.

As described above, the width 300w of the third semiconductor chip 300 may be substantially equivalent to the width 100w of the first semiconductor chip 100. However, in some implementations, the thickness of the third semiconductor chip 300 is not specifically limited. For example, the thickness of the third semiconductor chip 300 may be greater than the thickness 100t of the first semiconductor chip 100 and the thickness 200t of the second semiconductor chip 200. In some implementations, the thickness of the third semiconductor chip 300 may be greater than the thickness 100t of the first semiconductor chip 100 and may be less than the thickness 200t of the second semiconductor chip 200.

In some implementations, the third semiconductor chip 300 may include a memory circuit, such as a static random access memory (SRAM). However, in some implementations, the third semiconductor chip 300 may include a logic circuit, an input/output circuit, and an analog circuit.

In some implementations, the third semiconductor chip 300 may be a dummy chip, whereby the heat dissipation characteristic may be improved by disposing a dummy chip on the first semiconductor chip 100.

The encapsulant 410 may encapsulate at least a portion of the second semiconductor chip 200. In some implementations, the encapsulant 410 may surround a side of the second semiconductor chip 200. The encapsulant 410 may be made of a heat curable resin, such as an epoxy resin, or an epoxy molding compound (EMC). In some implementations, the process for molding the second semiconductor chip 200 with the encapsulant 410 may be performed by a compression molding or a transfer molding.

The third through via 420 may penetrate the encapsulant 410 and may electrically connect the first semiconductor chip 100 and the rewiring structure 500. As the width 200w of the second semiconductor chip 200 may be less than the width 100w of the first semiconductor chip 100, the third through via 420 may be additionally disposed around the second semiconductor chip 200.

The third through via 420 may supply power to the first semiconductor chip 100 together with the second through via 230. For example, the third through via 420 may supply power to the first semiconductor chip 100 through the back side wiring structure 120 of the first semiconductor chip 100. Accordingly, the region of the first semiconductor chip 100 that has a difficulty in receiving the power through the second through via 230 because of a width difference between the first semiconductor chip 100 and the second semiconductor chip 200 is included, and power may be uniformly supplied to the entire region of the first semiconductor chip 100, thereby more efficiently improving the power characteristic of the first semiconductor chip 100.

The conductive material, for example, aluminum (Al), copper (Cu), gold (Au), silver (Ag), platinum (Pt), tin (Sn), chromium (Cr), palladium (Pd), tin (Pb), titanium (Ti), or alloys thereof may be used as a material for forming the third through via 420, and it is not limited thereto.

In some implementations, the rewiring structure 500 may be disposed on the second semiconductor chip 200. For example, the rewiring structure 500 may be disposed on the back side 200B that is an opposite side of the front side 200F facing the first semiconductor chip 100 of the second semiconductor chip 200. Accordingly, the second semiconductor chip 200 may be disposed between the first semiconductor chip 100 and the rewiring structure 500.

The rewiring structure 500 may include an insulation layer 410 and a wiring layer 420 and may further include a via 430. In some implementations, the respective numbers of the insulation layer 410, the wiring layer 420, and the via 430 are not specifically limited, and each number of the insulation layer 410, the wiring layer 420, and/or the via 430 may be singular or plural

The insulation layer 410 may include, for example, a photo-imageable dielectric (PID) (or a photosensitive insulator). The photo-imageable dielectric (PID) may include a polyimide-based photosensitive polymer, a novolak-based photosensitive polymer, a polybenzoxazole, a silicon-based polymer, an acrylate-based polymer, or an epoxy-based polymer. The insulation layer 410 may be made of, for example, an inorganic dielectric material such as a silicon nitride or a silicon oxide.

The wiring layer 420 may be disposed on the insulation layer 410 or may be buried in the insulation layer 410. The conductive material, for example, aluminum (Al), copper (Cu), gold (Au), silver (Ag), platinum (Pt), tin (Sn), chromium (Cr), palladium (Pd), tin (Pb), titanium (Ti), or alloys thereof may be used as a material for forming the wiring layer 420, and it is not limited thereto.

The wiring layer 420 may include a pad 420p electrically connected to the connection structure 600. The pad 420p may be included in the wiring layer 420 disposed on a lowermost side of the wiring layer 420, and may be exposed through an opening of the insulation layer 410 disposed on a lowermost side of the insulation layer 410.

The via 430 may penetrate the insulation layer 410 and may connect the wiring layers 420 disposed on different layers. In some implementations, the via 430 may have a cylindrical shape, and in some implementations the via 430 may have a tapered shape of which the diameter is narrowed in a direction to a second side from a first side. The material for forming the via 430 may use the same material as the material for forming the wiring layer 420.

The connection structure 600 may be disposed on the rewiring structure 500 and may connect the semiconductor package 1000A to other constituent elements such as a printed circuit board. The connection structure 600 may contact the pad 420p and may be directly connected to the same. The material for forming the connection structure 600 may use copper (Cu), palladium (Pd), bismuth (Bi), antimony (Sb), tin (Sn), silver (Ag), or alloys thereof such as a tin-silver (SnAg) alloy. In some implementations, the connection structure 600 may be a solder ball.

In FIG. 1, the first semiconductor chip 100 may be disposed on the second semiconductor chip 200, and the semiconductor package 1000A may supply power to the first semiconductor chip 100 through the back side wiring structure 120 and the through via 230 of the second semiconductor chip 200. Accordingly, the power characteristic of the first semiconductor chip 100 may be improved. In some implementations, the signal transmission path and the resistance between the first semiconductor chip 100 and the second semiconductor chip 200 by processing the thickness of the first semiconductor chip 100 to be less than the thickness of the second semiconductor chip 200. Additionally, power may be efficiently supplied to the third semiconductor chip 300 through the through via 230 of the second semiconductor chip 200.

When the first semiconductor chip 100 includes a logic circuit generating heat, the first semiconductor chip 100 is disposed on an upper side of the second semiconductor chip 200 so the heat generated by the first semiconductor chip 100 may be efficiently discharged to the outside of the semiconductor package. As the third semiconductor chip 300 is additionally disposed on an upper side of the first semiconductor chip 100, the heat generated by the first semiconductor chip 100 may be more efficiently discharged to the outside of the semiconductor package through the third semiconductor chip 300. Additionally, in some implementations, no back side wiring structure is formed on the second semiconductor chip 200 and the third semiconductor chip 300, thereby minimizing the manufacturing cost of the semiconductor package.

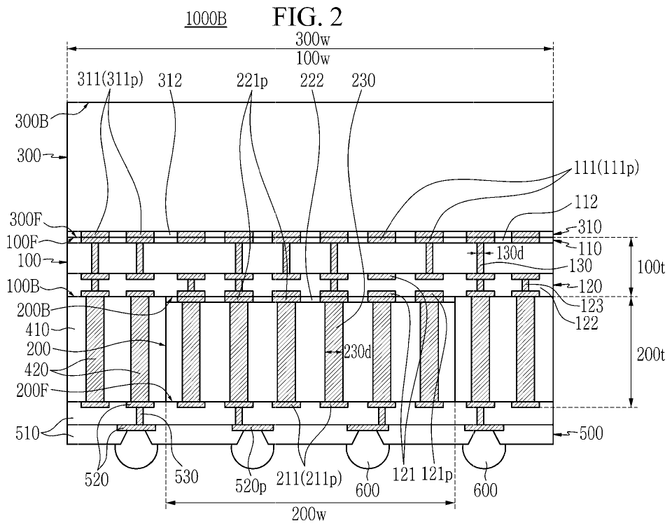

FIG. 2 shows a cross-sectional view of an example of a semiconductor package according to some implementations. In FIG. 2, regarding the semiconductor package 1000B, a disposition form of the second semiconductor chip 200 is different from the case of the semiconductor package 1000A of FIG. 1.

In some implementations, the second semiconductor chip 200 may be disposed so that the back side 200B faces the back side 100B of the first semiconductor chip 100. In some implementations, the second semiconductor chip 200 may be disposed in a face-down form so that the third connection pad 211p faces a lower side of the semiconductor package 1000B. Accordingly, the front side 200F of the second semiconductor chip 200 may face the rewiring structure 500. When the second semiconductor chip 200 is disposed in the face-down form, it may be advantageous to a routing when connected to an external element.

The insulation layer 212 used to hybrid-bonding may not a disposed on a side of the third connection pad 211p of the second semiconductor chip 200.

The via pad 221p disposed on the back side 200B of the second semiconductor chip 200 may be hybrid-bonded to the second connection pad 121p of the first semiconductor chip 100. However, in some implementations, the via pad 221p may be indirectly bonded to the second connection pad 121p through a bump.

In some implementations, an insulation layer 222 may be disposed on a side of the via pad 221p. When the first semiconductor chip 100 and the second semiconductor chip 200 are connected by hybrid-bonding, the insulation layer 222 disposed on a side of the via pad 221p may directly contact the insulation layer 122 disposed on a side of the second connection pad 121p and may be bonded to the same. However, with respect to the insulation layer 222 disposed on a side of the via pad 221p, there may be a gap between two insulation layers depending on a material and a forming method of the insulation layer 122 disposed on a side of the second connection pad 121p.

Descriptions of other elements correspond to that described above with respect to the semiconductor package 1000A according to some implementations are not repeated.

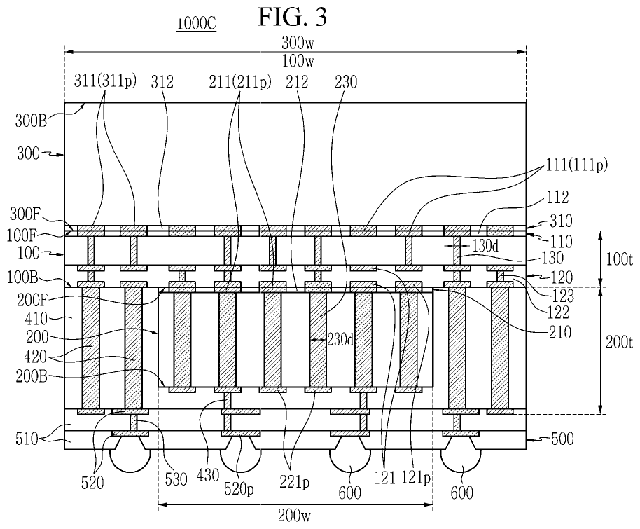

FIG. 3 shows a cross-sectional view of an example of a semiconductor package according to some implementations. In FIG. 3, regarding the semiconductor package 1000C, the encapsulant 410 may surround a side of the second semiconductor chip 200 and may be further disposed between the second semiconductor chip 200 and the rewiring structure 500. For example, the encapsulant 410 may surround a side of the second semiconductor chip 200 and may cover the back side 200B. When the semiconductor package 1000c includes the semiconductor package 1000B of FIG. 2, the encapsulant 410 may surround a side of the second semiconductor chip 200 and may cover the front side 200F.

In some implementations, the semiconductor package 1000C may further include a via 430 for penetrating the encapsulant 410 and connecting the second semiconductor chip 200 and the rewiring structure 500. For example, the via 430 may be connected to the second through via 230 through the via pad 221p.

Descriptions of other elements correspond to that described above with respect to the semiconductor package 1000A according to some implementations are not repeated.

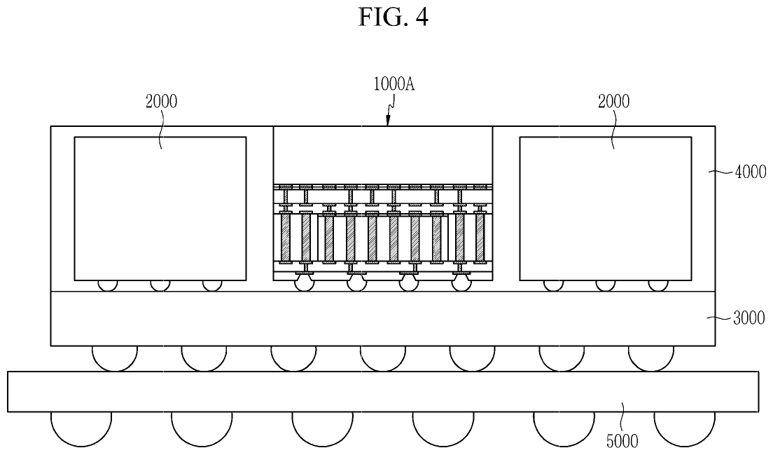

FIG. 4 shows a cross-sectional view of an example of a 2.5D package including a semiconductor package according to some implementations. In FIG. 4, a 2.5D package may include the semiconductor package 1000A according to some implementations. For example, the 2.5D package may be formed by disposing the semiconductor package 1000A and a memory chip 2000 in parallel to each other on the interposer substrate 3000 and encapsulating the same with an encapsulant 4000. In some implementations, the memory chip 2000 may be a high bandwidth memory (HBM), and a plurality of memory chips 2000 may be installed on the interposer substrate 3000. In some implementations, the 2.5D package may be installed on a main board 5000. In some implementations, the 2.5D package may also include the semiconductor packages 1000B and 1000C in FIGS. 2 and 3.

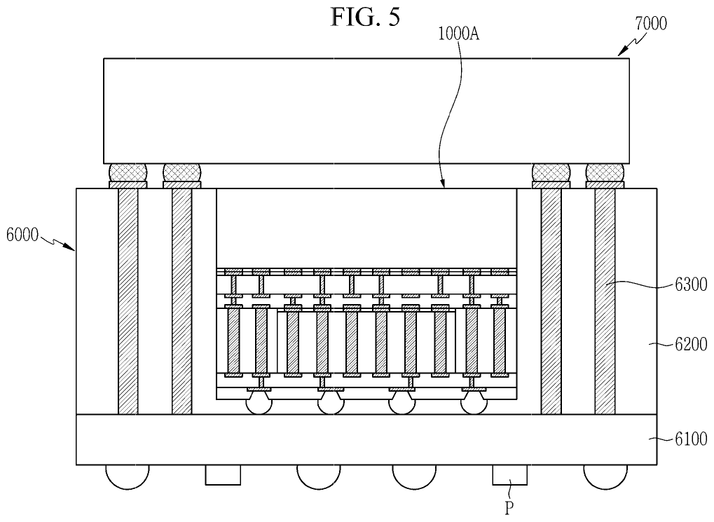

FIG. 5 shows a cross-sectional view of an example of a package on package (POP) including a semiconductor package according to some implementations. In FIG. 5, a package on package (POP) may include the semiconductor package 1000A according to some implementations. For example, the package on package may be manufactured by disposing the semiconductor package 1000A on a substrate 6100, encapsulating the same with an encapsulant 6200 to manufacture a lower semiconductor package 6000, and installing an upper semiconductor package 7000 on the lower semiconductor package 6000. The upper semiconductor package 7000 may be electrically connected to the substrate 6100 of the lower semiconductor package 6000 through a conductive post 6300. Passive parts (P), such as a capacitor, in addition to the solder ball may be disposed on a lower side of the substrate 6100. In some implementations, the package on package may also include the semiconductor packages 1000B and 1000C.

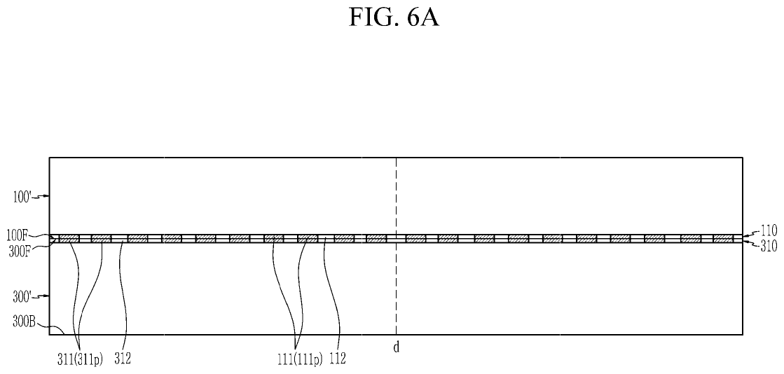

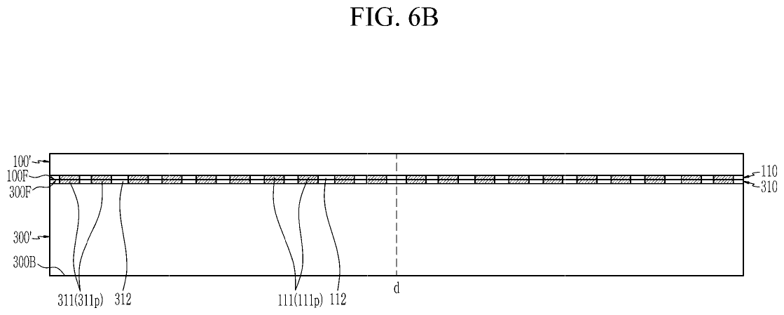

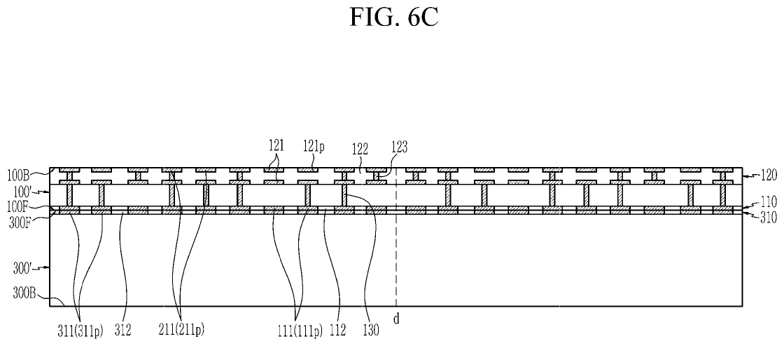

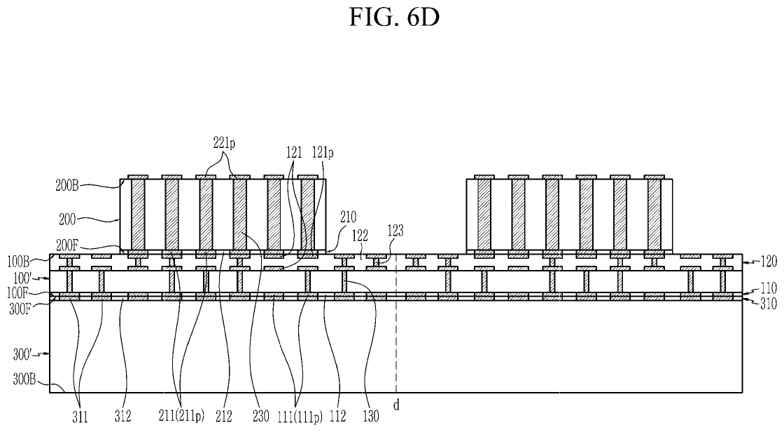

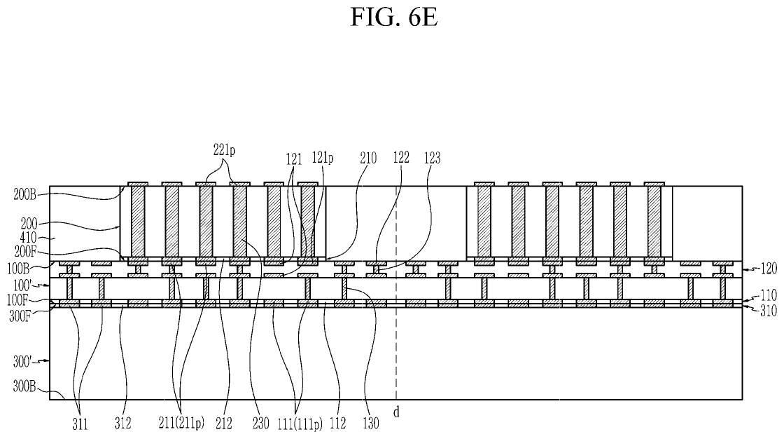

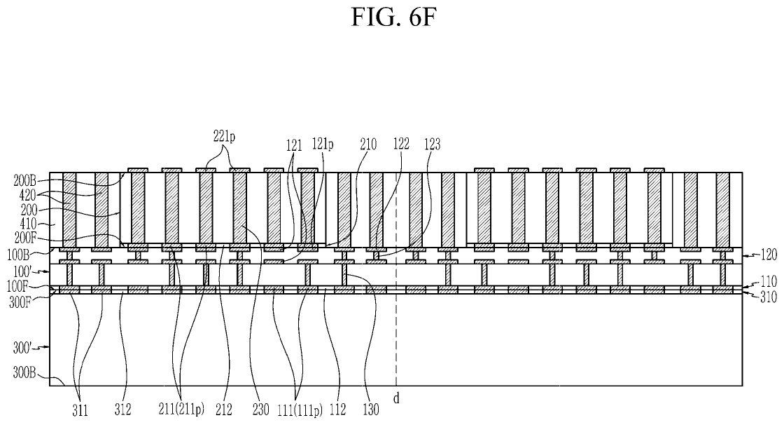

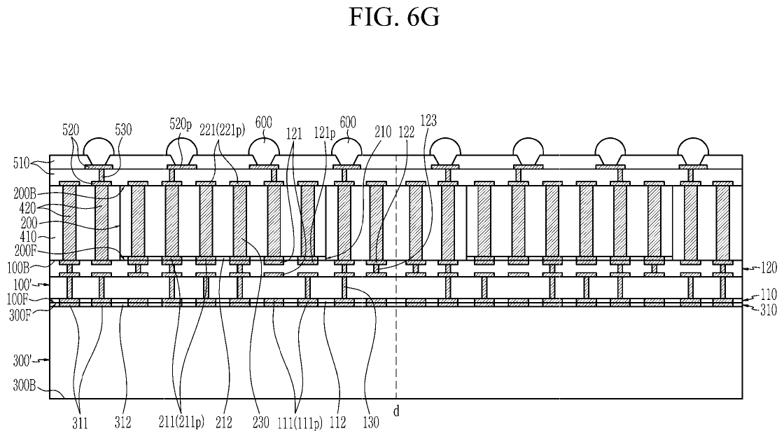

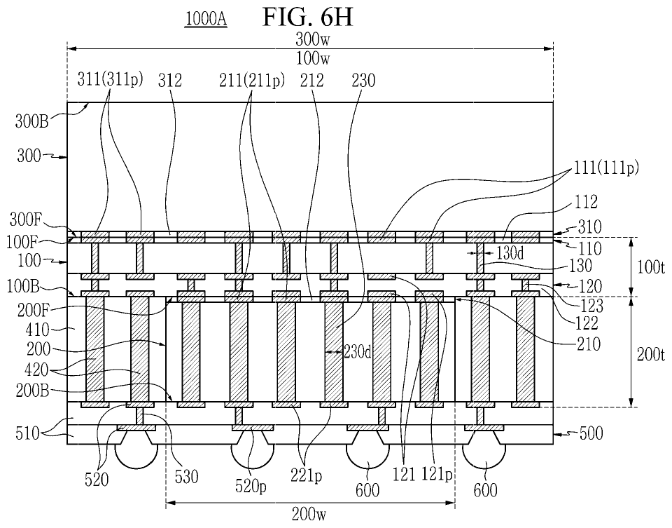

FIG. 6A to FIG. 6H show examples of processing diagrams for manufacturing a semiconductor package according to some implementations. In FIG. 6A to FIG. 6H, a method for manufacturing a semiconductor package may include providing a first wafer structure 300′ in which a first front side wiring structure 310 is formed, providing a second wafer structure 100′ in which a second front side wiring structure 110 is formed, bonding the first wafer structure 300′ and the second wafer structure 100′, forming a first through via 130 to be connected to the second front side wiring structure 110 in the second wafer structure 100′, forming a back side wiring structure 120 to be connected to the first through via 130 in the second wafer structure 100′, disposing the semiconductor chip 200 including the second through via 230 in the second wafer structure 100′, and dicing the bonded first wafer structure 300′ and the second wafer structure 100′. In some implementations, the method may further include, before the forming of a first through via 130, reducing the thickness of the second wafer structure 100′ by processing an opposite side of the side where the second front side wiring structure 110 of the second wafer structure 100′ is formed.

In some implementations, the diced first wafer structure 300′ corresponds to the third semiconductor chip 300 of the semiconductor package 1000A (in FIG. 1), and the diced second wafer structure 100′ corresponds to the first semiconductor chip 100 of the semiconductor package 1000A.

For better understanding and ease of description, the second wafer structure in which the front side wiring structure 110 is formed, second wafer structure in which the first through via 130 is additionally formed, and the second wafer structure in which the back side wiring structure 120 is additionally formed will all be referred to as the second wafer structure 100′.

In FIG. 6A, the first wafer structure 300′ and the second wafer structure 100′ may be bonded by disposing the respective front sides 300F and 100F of the first wafer structure 300′ and the second wafer structure 100′ to face each other and performing a wafer to wafer hybrid-bonding.

In FIG. 6B, the processing of an opposite side of the side on which the second front side wiring structure 110 of the second wafer structure 100′ is formed may be performed by removing a portion of the second wafer structure 100′ in the thickness direction. The processing may be performed by grinding, chemical mechanical polishing (CMP), dry etching, wet etching, etc. Accordingly, the first semiconductor chip 100 may be thin and may reduce the signal transmission path and resistance.

In FIG. 6C, the forming of a first through via 130 may be performed by the via-last method while the second wafer structure 110′ is bonded on the first wafer structure 300′. However, in some implementations, the first through via 130 may be formed by the via-first or via-middle method before the second wafer structure 110′ is bonded in the first wafer structure 300′.

Additionally, the forming of a back side wiring structure 120 may be performed by forming the wiring layer 121 and the insulation layer 122 in the direction to the back side 100B from the front side 100F of the second wafer structure 110′. In some implementations, the respective numbers of the wiring layer 121 and the insulation layer 122 are changeable. The wiring layer 121 may be a protruding (extending) pattern disposed on the insulation layer 122 or may be a buried pattern that is buried in the insulation layer 122.

In FIG. 6D, the disposing of the semiconductor chip 200 including the second through via 230 in the second wafer structure 100′ may be performed by disposing the back side 100B of the second wafer structure 100′ and the front side 200F of the semiconductor chip 200 to face each other and performing a chip to wafer hybrid-bonding.

In FIG. 6E, the method may further include encapsulating the semiconductor chip 200 with an encapsulant 410. In some implementations, the encapsulating of the semiconductor chip 200 with an encapsulant 410 may be performed by a compression molding or a transfer molding.

In FIGS. 6F to 6G, the method may further include forming a rewiring structure 500 electrically connected to the semiconductor chip 200 on the encapsulant 410. In some implementations, the method for manufacturing a semiconductor package may further include forming a third through via 420 penetrating the encapsulant 410 and electrically connecting the second wafer structure 100′ and the rewiring structure 500. In some implementations, the method for manufacturing a semiconductor package may further include disposing the connection structure 600 in the rewiring structure 500.

The forming of a third through via 420 may be performed by forming a via hole in the encapsulant 410 by use of a laser beam drill, forming a seed layer along a wall of the via hole, and forming a plating layer on the seed layer.

The forming of a rewiring structure 500 may be performed by repeating the forming of a wiring layer 520, the forming of an insulation layer 510 for covering the wiring layer 520, and the forming of a via 530 penetrating the insulation layer 510 and connected to the wiring layer 520. The forming of a wiring layer 520 may be performed by forming a seed layer on the encapsulant 410 or the insulation layer 510 and forming a plating layer on the seed layer. The forming of a via 530 may be performed by forming a via hole in the insulation layer 510 by use of a laser beam drill, forming a seed layer along a wall of the via hole, and forming a plating layer on the seed layer.

Before disposing the connection structure 600, an opening may be formed in the insulation layer 510 to expose the pad 520p. Accordingly, the connection structure 600 may be disposed on the pad 520p and may be electrically connected to the rewiring structure 500 through the pad 520p.

The dicing of the bonded first wafer structure 100′ and the second wafer structure 300′ may be performed by dicing the first wafer structure 100′ and the second wafer structure 300′ along a dicing line (d) by use of laser beams or blades. For example, the encapsulant 410 and the rewiring structure 500 may be diced together.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a first semiconductor chip having a front side and a back side that is opposite to the front side, the first semiconductor chip including a front side wiring structure disposed on the front side, a back side wiring structure disposed on the back side, and a first through-via electrically connected to the front side wiring structure and the back side wiring structure;
a second semiconductor chip disposed on the back side of the first semiconductor chip and including a second through-via; and
a third semiconductor chip disposed on the front side of the first semiconductor chip,
wherein the first semiconductor chip is configured to receive power through the second through-via, and
wherein a thickness of the second semiconductor chip is greater than a thickness of the first semiconductor chip.

2. The semiconductor package of claim 1, wherein a width of the first semiconductor chip is greater than a width of the second semiconductor chip.

3. The semiconductor package of claim 1, wherein the third semiconductor chip is configured to receive power through the first semiconductor chip.

4. The semiconductor package of claim 1, wherein a width of the third semiconductor chip is equal to a width of the first semiconductor chip.

5. The semiconductor package of claim 1,
wherein a back side wiring structure of the first semiconductor chip includes a first connection pad,
wherein the second semiconductor chip includes a second connection pad, and
wherein the first connection pad directly contacts the second connection pad.

6. The semiconductor package of claim 1,
wherein a front side wiring structure of the first semiconductor chip includes a first connection pad,
wherein the third semiconductor chip includes a second connection pad, and
wherein the first connection pad directly contacts the second connection pad.

7. The semiconductor package of claim 1, wherein a thickness of the first semiconductor chip is 2 to 10 μm.

8. The semiconductor package of claim 1, wherein a thickness of the second semiconductor chip is 20 to 100 μm.

9. The semiconductor package of claim 1,
wherein the first semiconductor chip includes a logic circuit, and
wherein the second semiconductor chip includes at least one of an input/output circuit and an analog circuit.

10. The semiconductor package of claim 9, wherein the third semiconductor chip includes a memory circuit.

11. The semiconductor package of claim 9, wherein the third semiconductor chip is a dummy chip.

12. A semiconductor package comprising:
a first semiconductor chip having a front side and a back side that is opposite to the front side, the first semiconductor chip including a front side wiring structure disposed on the front side, a back side wiring structure disposed on the back side, and a first through-via electrically connected to the front side wiring structure and the back side wiring structure;
a second semiconductor chip disposed on the back side of the first semiconductor chip and including a second through-via electrically connected to the first semiconductor chip;
a third semiconductor chip disposed on the front side of the first semiconductor chip;
an encapsulant encapsulating at least a portion of the second semiconductor chip; and
a rewiring structure disposed on the second semiconductor chip,
wherein a diameter of the first through-via is less than a diameter of the second through-via.

13. The semiconductor package of claim 12, wherein a diameter of the first through-via is 0.1 to 1 μm.

14. The semiconductor package of claim 12, wherein a diameter of the second through-via is 2 to 50 μm.

15. The semiconductor package of claim 12, further comprising:
a third through-via extending into the encapsulant to electrically connect the first semiconductor chip and the rewiring structure, and configured to supply power to the first semiconductor chip.

16. The semiconductor package of claim 12, further comprising a connection structure disposed on the rewiring structure.

17. A method for manufacturing a semiconductor package comprising:
providing a first wafer structure on which a first front side wiring structure is formed;
providing a second wafer structure on which a second front side wiring structure is formed;
bonding the first wafer structure to the second wafer structure;
forming a first through-via in the second wafer structure to be connected to the second front side wiring structure;
forming a back side wiring structure in the second wafer structure to be connected to the first through-via;
disposing a semiconductor chip including a second through-via on the second wafer structure; and
dicing the bonded first wafer structure and the second wafer structure.

18. The method of claim 17, further comprising, before forming the first through-via, reducing a thickness of the second wafer structure by processing a second side of the second wafer structure that is opposite to a first side of the second wafer on which the second front side wiring structure is formed.

19. The method of claim 17, further comprising:
encapsulating the semiconductor chip with an encapsulant; and
forming a rewiring structure electrically connected to the semiconductor chip on the encapsulant.

20. The method of claim 19, further comprising:
forming a third through-via extending into the encapsulant; and
electrically connecting the second wafer structure and the rewiring structure.
